(19) United States
(12) Patent Application Publication
(10) Pub. No.: US 2025/0298954 A1
(43) Pub. Date: Sep. 25, 2025

(54) WIRING METHOD, DEVICE AND EQUIPMENT OF QUANTUM CHIP AND COMPUTER-READABLE STORAGE MEDIUM

(71) Applicant: YANGTZE DELTA INDUSTRIAL INNOVATION CENTER OF QUANTUM SCIENCE AND TECHNOLOGY, Suzhou (CN)

(72) Inventors: Bin YANG, Suzhou (CN); Xiang ZHANG, Suzhou (CN); Weigui GUO, Suzhou (CN); Xuefei LIU, Suzhou (CN)

(21) Appl. No.: 19/174,980

(22) Filed: Apr. 10, 2025

Related U.S. Application Data
(63) Continuation of application No. PCT/CN2024/105304, filed on Jul. 12, 2024.

(30) Foreign Application Priority Data
Sep. 7, 2023 (CN) 202311149558.1

(51) Int. Cl. G06F 30/394; G06N 3/08

(52) U.S. Cl. CPC G06F 30/394; G06N 3/08

(57) ABSTRACT

The application discloses a wiring method, device and equipment for a quantum chip and a computer-readable storage medium, and relates to the technical field of quantum chips. A Monte Carlo tree model is used to calculate an optimal wiring path between an initial interface and a corresponding first virtual pin. Since the Monte Carlo tree model can conduct mathematical model training and self-learning according to the wiring result obtained after wiring in the past, the optimal wiring result on the overall level is obtained, efficient, accurate and automatic wiring of the two-dimensional quantum chip is achieved, and the wiring efficiency of the quantum chip is improved to the maximum extent. Through the arrangement of the first virtual pin, the control line in the qubit is connected with the external pin of the quantum chip through the initial interface and the first virtual pin.

### CROSS-REFERENCE TO RELATED APPLICATIONS

The present application is a continuation of International Application No. PCT/CN2024/105304, with an international filing date of Jul. 12, 2024, which is based upon and claims priority to Chinese Patent Application No. 202311149558.1, filed on Sep. 7, 2023, the entire contents of all of which are incorporated herein by reference.

### TECHNICAL FIELD

The present disclosure relates to the field of quantum chip technology, particularly to a wiring method, device and equipment for a quantum chip and computer-readable storage medium.

### BACKGROUND

A quantum chip is a core component of a quantum computer, integrating qubits and related circuits on a substrate to carry the function of quantum information processing. Usually, a quantum chip includes a plurality of quantum devices, such as qubits and resonant cavities. As the number of qubits in a quantum chip increases, the design difficulty grows geometrically. In the design process of large-scale quantum chip, the most time-consuming and energy-consuming problem is undoubtedly how to wire. For example, in order to realize the driving of the qubits, it usually relies on two types of control lines for regulation. The first is an xy control line for microwave signals, and the second is a z control line for magnetic flux signals. A control line interface on the qubit is connected with an external pin of the quantum chip through a connecting line, so as to obtain external control signals through a control channel corresponding to the external pin, and realize driving and frequency regulation of the qubit.

Due to the exponential annual growth of qubits in the current quantum chips, manual wiring cannot meet the requirements of efficient layout design and iteration. The wiring of quantum chip in the prior art is generally achieved by automatic wiring. The existing automatic wiring method usually adopts a greedy algorithm that automatically selects a path with the shortest distance between a qubit and an external pin for wiring, without considering the problem from the overall optimization or the line distance among the connecting lines. Regarding more complex wiring scenarios such as a two-dimensional quantum chip structure, due to the fact that the two-dimensional quantum chip structure comprises a plurality of qubit rows, and each qubit row comprises a plurality of qubits, if the existing automatic wiring method is still used for wiring, the spacing between connecting lines is often too narrow, leading to signal crosstalk and other problems. The low wiring success rate and greatly limited application make it impossible to meet the complex layout and wiring situation after the exponential growth of qubits in the future.

### SUMMARY

The disclosure provides a wiring method, device for a quantum chip and a computer-readable storage medium, which realize high-efficiency and accurate automated wiring of a two-dimensional quantum chip. This maximally improves the wiring efficiency of the quantum chip, ensures that the distance between connecting lines from an initial interface to an external pin of the quantum chip is not smaller than a preset minimum line distance, and reduces the probability of occurrence of problems such as signal crosstalk.

In order to solve the above technical problem, the present disclosure provides a wiring method for quantum chip. The quantum chip comprises m rows of qubit, and one row of qubit comprises n qubits, wherein both m and n are positive integers not less than 1, and for any one of the qubits, the wiring method comprises:
determining an initial interface corresponding to the qubit according to the position of the qubit on the quantum chip;
determining a first virtual pin according to the initial interface, so that a control line in the qubit is connected with a first external pin of the quantum chip through the initial interface and the first virtual pin. A first distance between the first virtual pins corresponding to any two of the initial interfaces is not less than a preset minimum line distance; and
determining a first optimal wiring path of a connecting line from the initial interface to a corresponding first virtual pin according to the initial interface, the first virtual pin and a Monte Carlo tree model, the Monte Carlo tree model is a mathematical model obtained by training on wiring results after wiring different qubits.

In one aspect, after determining a first virtual pin according to the initial interface, the method further comprises:
determining a second virtual pin according to the first virtual pin, so that a control line in the qubit is connected with a second external pin of the quantum chip through the initial interface, the first virtual pin and the second virtual pin. A second distance between the second virtual pins corresponding to any two of the first virtual pins is not less than a product of the first distance and a preset expansion parameter, and the expansion parameter is greater than 1.

In one aspect, a first horizontal ordinate formula for a horizontal ordinate of the second virtual pin is xᵢ²=xᵢ¹±d, and a first vertical ordinate formula for a vertical ordinate of the second virtual pin is

$${y}_{i}^{2} = {y}_{[ b / 2 ]}^{2} + ( [ \frac{b}{2} ] - i ) \cdot {s}^{2} ;$$

wherein, y_{[b/2]}²=y_{[b/2]}¹, xᵢ¹ is a horizontal ordinate of the i^{th} first virtual pin, xᵢ² is a horizontal ordinate of the i^{th} second virtual pin, d is a distance between the second virtual pin and the first virtual pin, yᵢ² is a vertical ordinate of the i^{th} second virtual pin, b is the number of the first virtual pin in the row of the qubit, y_{[b/2]}² is a vertical ordinate of the b/2^{th} second virtual pin, y_{[b/2]}¹ is a vertical ordinate of the b/2^{th} first virtual pin, and s² is a second distance between each of the second virtual pins.

In one aspect, after determining a first virtual pin according to the initial interface, the method further comprises:
determining a third virtual pin according to the first virtual pin, so that a control line in the qubit is connected with a third external pin of the quantum chip through the initial interface, the first virtual pin and the third virtual pin. A third distance between the third virtual pins corresponding to any two of the first virtual pins is not less than a preset minimum line distance; and
the third virtual pin comprises an upper virtual pin and a lower virtual pin, the first virtual pin of the qubit row of the first row corresponding one-to-one with the upper virtual pin, the first virtual pin of the qubit row of the last row corresponding one-to-one with the lower virtual pin. The upper virtual pin is arranged above the qubit row of the first row and the lower virtual pin is arranged below the qubit row of the last row. A first distance between the upper virtual pin and the qubit row of the first row and a second distance between the lower virtual pin and the qubit row of the last row are preset optimal pin distances.

In one aspect, the calculation formula of the optimal pin distance is as follows:

$$d = arg min ( {\sum }_{i}^{n} ( {L}_{1 i} + {L}_{2 i} ) ) ;$$

wherein, d is the optimal pin distance, n is a total number of connecting lines connecting each of the first virtual pins and the corresponding third virtual pin, L₁ᵢ is a distance from the i^{th} first virtual pin to the corresponding i^{th} third virtual pin, and L₂ᵢ is a distance from the i^{th} third virtual pin to a peripheral pin.

In one aspect, a second horizontal ordinate formula for a horizontal ordinate of the third virtual pin is xᵢ³=x_{q1}+i·(x_{qm}−x_{q1})/(n³−1), and a second vertical ordinate formula for a vertical ordinate of the third virtual pin is

$${y}_{i}^{3} = {y}_{q 1} \pm d ;$$

wherein, xᵢ³ is a horizontal ordinate of the i^{th} third virtual pin, x_{q1} is a horizontal ordinate of an initial qubit of the qubit row of the first row or the qubit row of the last row, x_{qm} is a horizontal ordinate of a middle qubit of the qubit row of the first row or the qubit row of the last row, n³ is the number of third virtual pins, yᵢ³ is a vertical ordinate of the i^{th} third virtual pin, y_{q1} is a vertical ordinate of an initial qubit of the qubit row of the first row or the qubit row of the last row, and d is a preset optimal pin distance.

In one aspect, after determining a third virtual pin according to the first virtual pin, the method further comprises:
determining a second optimal wiring path of a connecting line from the first virtual pin to a corresponding third virtual pin according to the first virtual pin, the third virtual pin and a Monte Carlo tree model.

In one aspect, after determining a second optimal wiring path of a connecting line from the first virtual pin to a corresponding third virtual pin according to the first virtual pin, the third virtual pin and a Monte Carlo tree model, the method further comprises:
connecting the third virtual pin with a corresponding third external pin according to the third virtual pin, the third external pin of the quantum chip and an A* algorithm, the third external pin corresponding one-to-one with the third virtual pin.

In one aspect, after determining a first optimal wiring path of a connecting line from the initial interface to a corresponding first virtual pin according to the initial interface, the first virtual pin and a Monte Carlo tree model, the method further comprises:
connecting the first virtual pin with a corresponding first external pin according to the first virtual pin, the first external pin of the quantum chip and an A* algorithm, the first external pin corresponding one-to-one with the first virtual pin.

In one aspect, the first virtual pin comprises a left half portion of the first virtual pin disposed on the left side of each of the qubit rows and a right half portion of the first virtual pin disposed on the right side of each of the qubit rows, and the calculation formula of the number of the left half portion of the first virtual pin is:

$${n}^{l 1} ( k ) = {n}_{xy}^{l} ( k ) + {n}_{z}^{l} ( k ) + {δ}^{l} ;$$

wherein, n^{l1}(k) is the number of the left half portion of the first virtual pin, n_{xy}^{l}(k) is the number of xy control lines disposed on the left side of each of the qubit rows, and n_{z}^{l}(k) is the number of z control lines disposed on the left side of each of the qubit rows;
the calculation formula of the number of the right half portion of the first virtual pin is:

$${n}^{r 1} ( k ) = {n}_{xy}^{r} ( k ) + {n}_{z}^{r} ( k ) + {δ}^{r} ;$$

wherein, n^{r1}(k) is the number of the right half portion of the first virtual pin, n_{xy}^{r}(k) is the number of xy control lines disposed on the right side of each of the qubit rows, n_{z}^{r}(k) is the number of z control lines disposed on the right side of each of the qubit rows, δ^{l} is 0 or 1, δ^{r} is 0 or 1, and δ^{l}+δ^{r}=1.

In one aspect, after determining a first optimal wiring path of a connecting line from the initial interface to a corresponding first virtual pin according to the initial interface, the first virtual pin and a Monte Carlo tree model, the method further comprises:
scoring wiring results of the first optimal wiring path according to a reward function; and
updating the Monte Carlo tree model according to the scoring result and a neural network model.

In one aspect, the reward function is defined as:

$$R ( s , a ) = \{ \begin{matrix}- α \sum {L}_{i} - β \sum {L}_{ri} - γ \sum {N}_{i} , & {s}^{′} ∈ t \\ 0 , & t ⋂ {s}^{′} = ∅\end{matrix} ;$$

wherein, s is a wiring state in the wiring process of the first optimal wiring path, a is a wiring action in the wiring process of the first optimal wiring path, Lᵢ is a wiring length of the first optimal wiring path, Lᵣᵢ is a Manhattan length between the i^{th} unwired initial interfaces, Nᵢ is the number of right angles in the wiring process of the first optimal wiring path, α, β and γ are weight coefficients in front of each item, s′ is a wiring state after the wiring action α is performed, and t is a state of completing the wiring of all the initial interfaces or a state where the wiring cannot be continued.

In one aspect, a loss function of the neural network model is:

$$L = {( R - v )}^{2} + {E}_{p} [ log ( {p}_{θ} ( s , a ) \cdot v ( s , a ) ] + α {\vert θ \vert}^{2} ;$$

wherein, L is the loss function, s is a wiring state in the wiring process of the first optimal wiring path, α is a wiring action in the wiring process of the first optimal wiring path, R is the reward function, v is a value function output by the neural network model when a wiring state s and a wiring action α are input to the neural network model, p_{θ} is a policy function output by the neural network model when a wiring state s and a wiring action α are input to the neural network model, α is a regularization parameter of the neural network model, and θ is a parameter of the neural network model.

In order to solve the above technical problem, the present disclosure further provides a wiring device for quantum chip. The quantum chip comprises m rows of qubit, and one row of qubit comprises n qubits, wherein both m and n are positive integers not less than 1, and for any one of the qubits, the wiring device comprising:
an initial interface determination module determining an initial interface corresponding to the qubit according to the position of the qubit on the quantum chip;
a first virtual pin interface determination module for determining a first virtual pin according to the initial interface, so that a control line in the qubit is connected with a first external pin of the quantum chip through the initial interface and the first virtual pin. A first distance between the first virtual pins corresponding to any two of the initial interfaces is not less than a preset minimum line distance; and
a first wiring module for determining a first optimal wiring path of a connecting line from the initial interface to a corresponding first virtual pin according to the initial interface, the first virtual pin and a Monte Carlo tree model, the Monte Carlo tree model is a mathematical model obtained by training on wiring results after wiring different qubits.

In order to solve the above technical problem, the present disclosure further provides a wiring equipment for quantum chip. The quantum chip comprises m rows of qubit, and one row of qubit comprises n qubits, wherein both m and n are positive integers not less than 1, and for any one of the qubits, the wiring equipment comprising:
a memory for storing a computer program; and
a processor for implementing the steps of a wiring method for quantum chip as described in any one of the above embodiments when executing the computer program.

In order to solve the above technical problem, the present disclosure further provides a computer-readable storage medium. The target computer-readable storage medium has a computer program stored thereon, the target computer program is executed by a processor to implement the steps of a wiring method for quantum chip as described in any one of the above embodiments.

The present disclosure discloses a wiring method for a quantum chip. A Monte Carlo tree model is used to calculate an optimal wiring path between an initial interface and a corresponding first virtual pin. Since the Monte Carlo tree model can conduct mathematical model training and self-learning according to the wiring result obtained after wiring in the past, the optimal wiring result on the overall level is obtained, efficient, accurate and automatic wiring of the two-dimensional quantum chip is achieved, and the wiring efficiency of the quantum chip is improved to the maximum extent. Through the arrangement of the first virtual pin, the control line in the qubit is connected with the external pin of the quantum chip through the initial interface and the first virtual pin. As the first distance between the first virtual pins is not less than the preset minimum line distance, it ensures that the line distance of the connecting lines from the initial interface to the external pin of the quantum chip is not smaller than the preset minimum line distance, and the probability of occurrence of problems such as signal crosstalk is reduced.

The present disclosure further provides a wiring device and equipment for a quantum chip and a computer-readable storage medium, which have the same effects as above.

### BRIEF DESCRIPTION OF THE DRAWINGS

In order to more clearly explain the technical solution in the embodiments of the present disclosure, drawings required in the prior art and the embodiments will be briefly described below. Obviously, the drawings in the following description are some embodiments of the present disclosure. For those skilled in the art, other drawings may be obtained from these drawings without any creative effort.

FIG. 1 is a flow diagram of a wiring method for a quantum chip provided by an embodiment of the present disclosure;

FIG. 2 is a schematic diagram of a greedy algorithm wiring provided by an embodiment of the present disclosure;

FIG. 3 is a schematic diagram of a Monte Carlo tree model wiring provided by an embodiment of the present disclosure;

FIG. 4 is a schematic diagram of wiring from a first virtual pin to a second virtual pin provided by an embodiment of the present disclosure;

FIG. 5 is a schematic diagram of wiring from a second virtual pin to a second external pin provided by an embodiment of the present disclosure;

FIG. 6 is a schematic diagram of wiring from a first virtual pin to an upper virtual pin provided by an embodiment of the present disclosure;

FIG. 7 is a schematic diagram of wiring from a first virtual pin to a lower virtual pin provided by an embodiment of the present disclosure;

FIG. 8 is a schematic diagram of a wiring area division provided by an embodiment of the present disclosure.

### DETAILED DESCRIPTION OF THE EMBODIMENTS

The core of the present disclosure is to provide a wiring method, device for a quantum chip and a computer-readable storage medium, which realize high-efficiency and accurate automatic wiring of a two-dimensional quantum chip. It maximally improves the wiring efficiency of the quantum chip, ensures that the distance of the connecting lines from an initial interface to an external pin of the quantum chip is not smaller than a preset minimum line distance, and reduces the probability of occurrence of problems such as signal crosstalk.

The technical solutions of the embodiments of the present disclosure will be described clearly and completely as follows with reference to the drawings in the embodiments of the present disclosure. Obviously, the described embodiments are part of, but not all of, the embodiments of the present disclosure. Based on the embodiments of the present disclosure, all the other embodiments obtained by those skilled in the art without paying any creative work fall within the protection scope of the present disclosure.

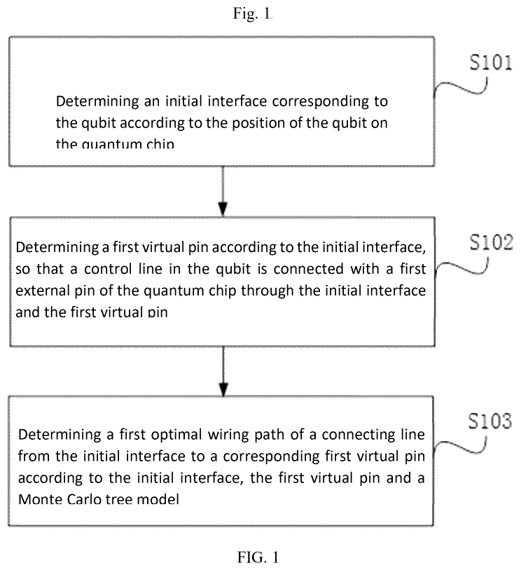

Referring to FIG. 1, FIG. 1 is a flow diagram of a wiring method for a quantum chip provided by an embodiment of the present disclosure. The quantum chip comprises m rows of qubit, and one row of qubit comprises n qubits, wherein both m and n are positive integers not less than 1, and for any one of the qubits, the wiring method comprising:

S101: determining an initial interface corresponding to the qubit according to the position of the qubit on the quantum chip.

In a specific embodiment, firstly, a parameterized quantum device library is established. The quantum device library specifically comprises quantum devices such as qubits, resonant cavities, etc. And then according to the needs of the quantum chip, the quantum devices in the established quantum device library are arranged at specific positions on the chip in accordance with a certain structure. In order to connect a control line interface on a qubit with an external pin of a quantum chip, so as to obtain external control signals through a control channel corresponding to the external pin and to realize driving and frequency regulation of the qubit, it is necessary to first determine the interface between the control line on the qubit and the qubit, i.e., the initial interface corresponding to the qubit.

S102: determining a first virtual pin according to the initial interface, so that a control line in the qubit is connected with a first external pin of the quantum chip through the initial interface and the first virtual pin. A first distance between the first virtual pins corresponding to any two of the initial interfaces is not less than a preset minimum line distance.

In a specific embodiment, for the convenience of wiring, the wiring of the whole quantum chip is divided into several steps and respective wiring tasks by using the virtual pins. The first step is to arrange a first virtual pin at the edge of each row of qubit layout, and divide the wiring task into two tasks, i.e., on-chip wiring and off-chip wiring, through the first virtual pin of each row. In other words, the wiring is led from inside the qubit to outside the qubit through the first virtual pin of each row.

The position of the first virtual pin may be set by a user. The first virtual pin may be disposed near an edge of a bit.

S103: determining a first optimal wiring path of a connecting line from the initial interface to a corresponding first virtual pin according to the initial interface, the first virtual pin and a Monte Carlo tree model, the Monte Carlo tree model is a mathematical model obtained by training on wiring results after wiring different qubits.

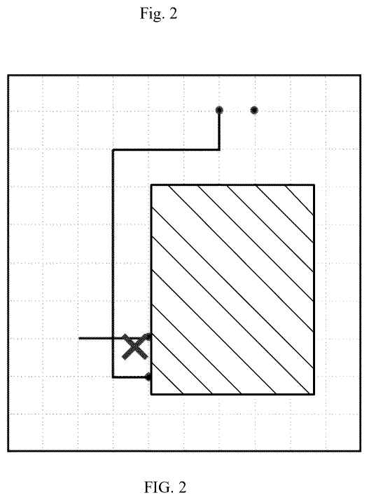

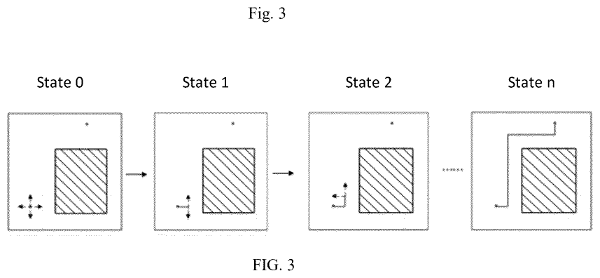

When using the traditional greedy algorithm for conventional wiring, the problem that the second line is blocked after the front line has been wired as shown in FIG. 2 arises (the shaded area shown in FIG. 2 is the area that cannot be wired at present, for example, there is an obstacle). It results in termination of the wiring. FIG. 2 is a schematic diagram of a greedy algorithm wiring provided by an embodiment of the present disclosure. In order to solve the problem, the present disclosure adopts a reinforcement learning method to enable an agent to automatically learn an optimal wiring strategy and learn to automatically explore a global wiring solution under various complex conditions. In a specific embodiment, firstly, a grid is divided in an area where wiring is required. The width of the grid is equal to the minimum constraint width between lines in the wiring, so that the wiring problem is converted into a graph problem, i.e., given G=(V, E), find a path Pᵢ and make any two paths P_{I}∩P_{J}=Ø. A state s is defined as a set contained in the graph G, including an initial interface and target interface information, the serial number of the wiring (serial wiring), the coordinates of the wiring head, etc.; a wiring action α is defined as a vector in four directions, i.e., up, down, left and right. For a specific wiring process, please refer to State 0, State 1, State 2 to State n in FIG. 3. FIG. 3 is a schematic diagram of a Monte Carlo tree model wiring provided by an embodiment of the present disclosure. The shaded area shown in FIG. 3 is the area that cannot be wired at present, e.g., there is an obstacle.

The present disclosure discloses a wiring method for a quantum chip. A Monte Carlo tree model is used to calculate an optimal wiring path between an initial interface and a corresponding first virtual pin. Since the Monte Carlo tree model can conduct mathematical model training and self-learning according to the wiring result obtained after wiring in the past, the optimal wiring result on the overall level is obtained, efficient, accurate and automatic wiring of the two-dimensional quantum chip is achieved, and the wiring efficiency of the quantum chip is improved to the maximum extent. Through the arrangement of the first virtual pin, the control line in the qubit is connected with the external pin of the quantum chip through the initial interface and the first virtual pin. The first distance between the first virtual pins is not less than the preset minimum line distance, which ensures that the line distance of the connecting lines from the initial interface to the external pin of the quantum chip is not smaller than the preset minimum line distance, and the probability of occurrence of problems such as signal crosstalk is reduced.

On the basis of the above embodiments, in some embodiments, after determining a first virtual pin according to the initial interface, the method further comprises:
determining a second virtual pin according to the first virtual pin, so that a control line in the qubit is connected with a second external pin of the quantum chip through the initial interface, the first virtual pin and the second virtual pin. A second distance between the second virtual pins corresponding to any two of the first virtual pins is not less than a product of the first distance and a preset expansion parameter, and the expansion parameter is greater than 1.

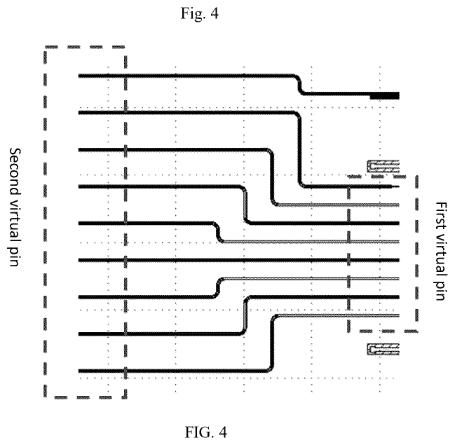

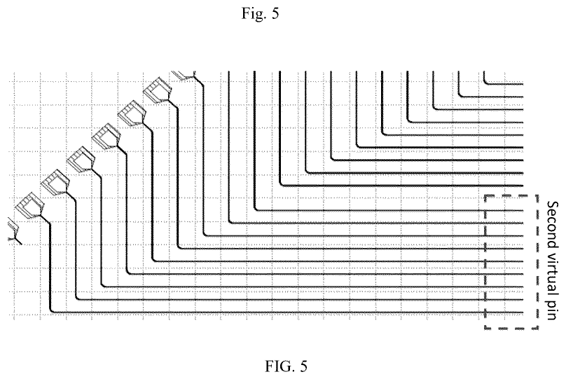

When the wiring is led out from the chip through the first virtual pin of each row, the first distance between the lines is not less than the preset minimum line distance. In order to reduce crosstalk between signals and to expand impedance matching in the future, it is necessary to increase the distance between lines led out from the first virtual pin, that is, to determine the second virtual pin according to the first virtual pin. Please refer to FIG. 4 and FIG. 5 for details. FIG. 4 is a schematic diagram of wiring from a first virtual pin to a second virtual pin provided by an embodiment of the present disclosure. FIG. 5 is a schematic diagram of wiring from a second virtual pin to a second external pin provided by an embodiment of the present disclosure. In a specific embodiment, a second virtual pin is arranged at a distance d from the first virtual pin, and d as a parameter can be adjusted. Usually, d≈10˜20 wₘᵢₙ, wherein wₘᵢₙ is a preset minimum line distance, and the second distance between the second virtual pins is generally 1.5-2.5 times of the distance between the first virtual pins.

In some embodiments, the first virtual pin corresponds one-to-one with the second virtual pin. In other words, for each first virtual pin, there is a second virtual pin corresponding thereto, and each first virtual pin is connected with the second virtual pin and then connected with the corresponding external pin, so that the line distance between the connecting lines is equal, which is convenient for subsequent expansion.

In some embodiments, a first horizontal ordinate formula for a horizontal ordinate of the second virtual pin is xᵢ²=xᵢ¹±d, and a first vertical ordinate formula for a vertical ordinate of the second virtual pin is

$${y}_{i}^{2} = {y}_{[ b / 2 ]}^{2} + ( [ \frac{b}{2} ] - i ) \cdot {s}^{2} ;$$

wherein, y_{[b/2]}²=y_{[b/2]}¹, xᵢ¹ is a horizontal ordinate of the i^{th} first virtual pin, xᵢ² is a horizontal ordinate of the i^{th} second virtual pin, d is a distance between the second virtual pin and the first virtual pin, is a vertical ordinate of the i^{th} second virtual pin, b is the number of the first virtual pin in the qubit row, y_{[b/2]}² is a vertical ordinate of the b/2^{th} second virtual pin, y_{[b/2]}¹ is a vertical ordinate of the b/2^{th} first virtual pin, and s² is a second distance between each of the second virtual pins.

It should be noted that in the above formula, [] means rounding up.

Both the horizontal ordinates of the first virtual pin and the vertical ordinates of the first virtual pin may be set by a user. The first virtual pin may be disposed near an edge of a bit.

According to the embodiment, the specific position of the second virtual pin is determined through the formula. It ensures accurate positioning, reduces crosstalk between signals, and facilitates the expansion of impedance matching in the future.

In some embodiments, after determining a first virtual pin according to the initial interface, the method further comprises:
determining a third virtual pin according to the first virtual pin, so that a control line in the qubit is connected with a third external pin of the quantum chip through the initial interface, the first virtual pin and the third virtual pin. A third distance between the third virtual pins corresponding to any two of the first virtual pins is not less than a preset minimum line distance; and
the third virtual pin comprising an upper virtual pin and a lower virtual pin, the first virtual pin of the qubit row of the first row corresponding one-to-one with the upper virtual pin, the first virtual pin of the qubit row of the last row corresponding one-to-one with the lower virtual pin. The upper virtual pin is arranged above the qubit row of the first row and the lower virtual pin is arranged below the qubit row of the last row. A first distance between the upper virtual pin and the qubit row of the first row and a second distance between the lower virtual pin and the qubit row of the last row are preset optimal pin distances.

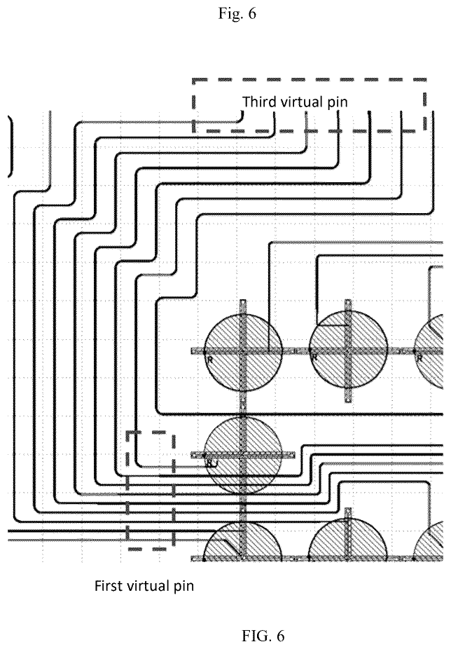

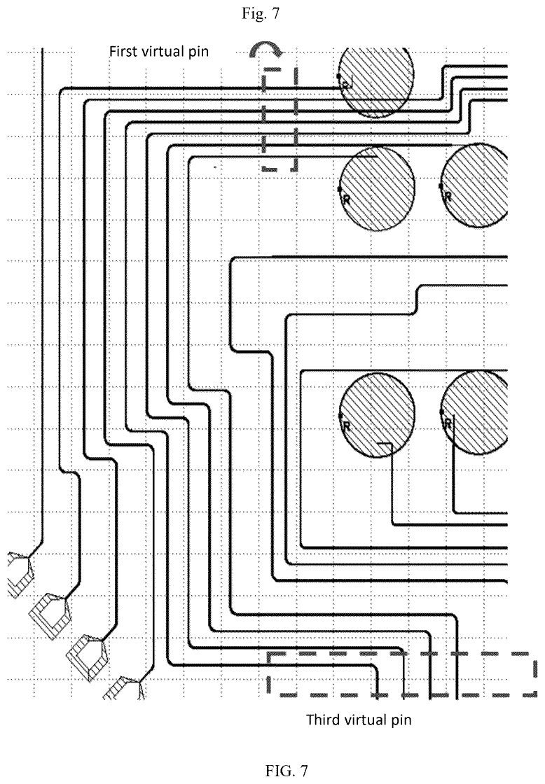

In a specific embodiment, for the two-dimensional structure commonly used today, the process of wiring from the first virtual pin to the third external pin corresponding to the qubit of the first and last rows is more complex with respect to the first two and the last two qubit rows in the plurality of qubit rows. Thus, the third virtual pin is arranged between the first virtual pin and the third external pin. Please refer to FIG. 6 and FIG. 7 for details. FIG. 6 is a schematic diagram of wiring from a first virtual pin to an upper virtual pin provided by an embodiment of the present disclosure. FIG. 7 is a schematic diagram of wiring from a first virtual pin to a lower virtual pin provided by an embodiment of the present disclosure.

In some embodiments, the calculation formula of the optimal pin distance is as follows:

$$d = arg min ( {\sum }_{i}^{n} ( {L}_{1 i} + {L}_{2 i} ) ) ;$$

wherein, d is the optimal pin distance, n is a total number of connecting lines connecting each of the first virtual pins and the corresponding third virtual pin, L₁ᵢ is a distance from the i^{th} first virtual pin to the corresponding i^{th} third virtual pin, and L₂ᵢ is a distance from the i^{th} third virtual pin to a peripheral pin.

In order to simplify the objective of reinforcement learning wiring, the third type of virtual pin is used as a wiring relay station for the qubits of the first and last rows. It ensures that the distance from the first virtual pin to the corresponding third virtual pin, and then to the corresponding third external pin is appropriate. In this embodiment, the optimal pin distance is determined through a formula, and the positioning is accurate.

In some embodiments, a second horizontal ordinate formula for a horizontal ordinate of the third virtual pin is xᵢ³=x_{q1}+i·(x_{qm}−x_{q1})/(n³−1), and a second vertical ordinate formula for a vertical ordinate of the third virtual pin is

$${y}_{i}^{3} = {y}_{q 1} \pm d ;$$

wherein, xᵢ³ is a horizontal ordinate of the i^{th} third virtual pin, x_{q1} is a horizontal ordinate of an initial qubit of the qubit row of the first row or the qubit row of the last row, x_{qm} is a horizontal ordinate of a middle qubit of the qubit row of the first row or the qubit row of the last row, n³ is the number of the third virtual pin, yᵢ³ is a vertical ordinate of the i^{th} third virtual pin, y_{q1} is a vertical ordinate of an initial qubit of the qubit row of the first row or the qubit row of the last row, and d is a preset optimal pin distance.

According to the embodiment, the specific position of the third virtual pin is determined through the formula, which ensures accurate positioning, wherein the initial qubit is a qubit at the edgemost position in the corresponding qubit row, and the middle qubit is a qubit at the midmost position in the corresponding qubit row.

In some embodiments, after determining a third virtual pin according to the first virtual pin, the method further comprises:
determining a second optimal wiring path of a connecting line from the first virtual pin to a corresponding third virtual pin according to the first virtual pin, the third virtual pin and a Monte Carlo tree model.

In this embodiment, due to the complexity of the wiring scenario, a Monte Carlo tree search is combined with a reinforcement learning algorithm to wire the connecting lines from the first virtual pin to the corresponding third virtual pin, so that the intelligent degree of the wiring process is improved.

In some embodiments, after determining a second optimal wiring path of a connecting line from the first virtual pin to a corresponding third virtual pin according to the first virtual pin, the third virtual pin and a Monte Carlo tree model, the method further comprises:
connecting the third virtual pin with a corresponding third external pin according to the third virtual pin, the third external pin of the quantum chip and an A* algorithm, the third external pin corresponding one-to-one with the third virtual pin.

In this embodiment, due to the simplicity of the wiring scenario, the traditional greedy algorithm, i.e., A* algorithm, is directly used for wiring between the third virtual pin and the third external pin of the quantum chip, so that the wiring efficiency is improved.

In some embodiments, after determining a first optimal wiring path of a connecting line from the initial interface to a corresponding first virtual pin according to the initial interface, the first virtual pin and a Monte Carlo tree model, the method further comprises:
connecting the first virtual pin with a corresponding first external pin according to the first virtual pin, the first external pin of the quantum chip and an A* algorithm, the first external pin corresponding one-to-one with the first virtual pin.

In this embodiment, due to the simplicity of the wiring scenario, the traditional greedy algorithm, i.e., A* algorithm, is directly used for wiring between the first virtual pin and the first external pin of the quantum chip, so that the wiring efficiency is improved.

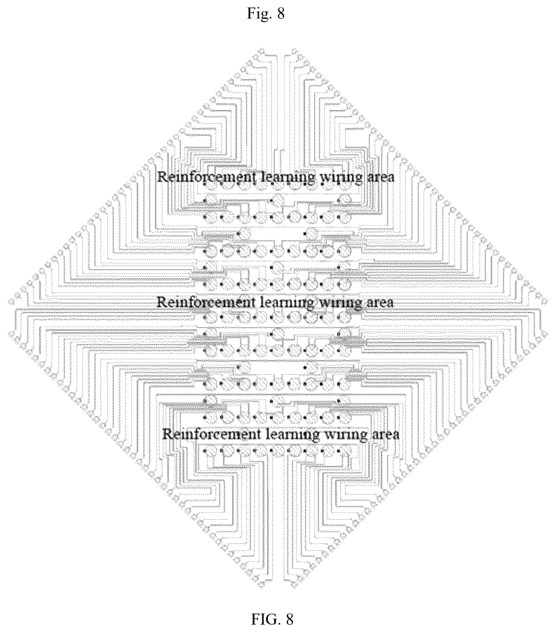

In a specific embodiment, the quantum chip is divided into a reinforcement learning wiring area and a non-reinforcement learning wiring area according to the complexity of the wiring. Regarding the non-reinforcement learning wiring area, due to the simplicity of the wiring scenario, the traditional greedy algorithm is directly used for wiring, so that the wiring efficiency is improved. Regarding the reinforcement learning wiring area, due to the complexity of the wiring scenario, the Monte Carlo search tree combined with the reinforcement learning algorithm is used for wiring. Please refer to FIG. 8 for details. FIG. 8 is a schematic diagram of a wiring area division provided by an embodiment of the present disclosure.

In some embodiments, the first virtual pin comprises a left half portion of the first virtual pin disposed on the left side of each of the qubit rows and a right half portion of the first virtual pin disposed on the right side of each of the qubit rows, and the calculation formula of the number of the left half portion of the first virtual pin is:

$${n}^{l 1} ( k ) = {n}_{xy}^{l} ( k ) + {n}_{z}^{l} ( k ) + {δ}^{l} ;$$

wherein, n^{l1}(k) is the number of the left half portion of the first virtual pin, n_{xy}^{l}(k) is the number of xy control lines disposed on the left side of each of the qubit rows, and n_{z}^{l}(k) is the number of z control lines disposed on the left side of each of the qubit rows;
the calculation formula of the number of the right half portion of the first virtual pin is:

$${n}^{r 1} ( k ) = {n}_{xy}^{r} ( k ) + {n}_{z}^{r} ( k ) + {δ}^{r} ;$$

wherein, n^{r1}(k) is the number of the right half portion of the first virtual pin, n_{xy}^{r}(K) is the number of xy control lines disposed on the right side of each of the qubit rows, n_{z}^{r}(k) is the number of z control lines disposed on the right side of each of the qubit rows, δ^{l} is 0 or 1, δ^{r} is 0 or 1, and δ^{l}+δ^{r}=1.

It should be noted that when the first virtual pin includes the left half portion of the first virtual pin disposed on the left side of each qubit row and the right half portion of the first virtual pin disposed on the right side of each qubit row, in combination with the formula of the wiring position of the second virtual pin provided in the above embodiment, it can be obtained that b=n^{l1}(k) or b=n^{r1}(k).

In order to balance the number of wirings in the left half portion and the right half portion in each layer of the quantum chip and prevent the problem of local connection line congestion in the quantum chip, in the embodiment, the number of the first virtual pins of the left half portion and the number of the first virtual pins of the right half portion is determined through a formula. It ensures that the number of the virtual pins on both sides is average, thereby adjusting the number of the connecting lines on both sides.

In some embodiments, after determining a first optimal wiring path of a connecting line from the initial interface to a corresponding first virtual pin according to the initial interface, the first virtual pin and a Monte Carlo tree model, the method further comprises:
scoring wiring results of the first optimal wiring path according to a reward function; and
updating the Monte Carlo tree model according to the scoring result and a neural network model.

In this embodiment, the Monte Carlo tree model is updated through a reward function. Specifically, when a termination condition is satisfied in the wiring process, the wiring is stopped and the wiring result is scored through a reward function, so as to guide the searching process of the Monte Carlo tree and improve the wiring capability.

In some embodiments, the reward function is defined as:

$$R ( s , a ) = \{ \begin{matrix}- α \sum {L}_{i} - β \sum {L}_{ri} - γ \sum {N}_{i} , & {s}^{′} ∈ t \\ 0 , & t ⋂ {s}^{′} = ∅\end{matrix} ;$$

wherein, s is a wiring state in the wiring process of the first optimal wiring path, a is a wiring action in the wiring process of the first optimal wiring path, Lᵢ is a wiring length of the first optimal wiring path, Lᵣᵢ is a Manhattan length between the i^{th} unwired initial interfaces, Nᵢ is the number of right angles in the wiring process of the first optimal wiring path, α, β and γ are weight coefficients in front of each item, S′ is a wiring state after the wiring action a is performed, and t is a state of completing the wiring of all the initial interfaces or a state where the wiring cannot be continued.

This embodiment provides a reward function. Specifically, if the existing wiring length is smaller, the remaining wiring length is smaller and the right-angle wiring is less, the agent will have a higher score. Therefore, the exploration strategy learned in the test process is more comprehensive and detailed, providing an opportunity for long-term exploration of an excellent wiring strategy.

In some embodiments, a loss function of the neural network model is:

$$L = {( R - v )}^{2} + {E}_{p} [ log ( {p}_{θ} ( s , a ) \cdot v ( s , a ) ] + α {\vert θ \vert}^{2} ;$$

wherein, L is the loss function, s is a wiring state in the wiring process of the first optimal wiring path, α is a wiring action in the wiring process of the first optimal wiring path, R is the reward function, v is a value function output by the neural network model when a wiring states and a wiring action α are input to the neural network model, p_{θ} is a policy function output by the neural network model when a wiring state s and a wiring action α are input to the neural network model, α is a regularization parameter of the neural network model, and θ is a parameter of the neural network model.

In a specific embodiment, an agent generates a large number of samples through the Monte Carlo tree to obtain training data for the training of the neural network. The Monte Carlo tree stores four main information for each action α in the wiring process, i.e., the number of visits to the edge N(s, a), the total action value W(s, a), the average action value Q(s, a) and the prior strategy probability P(s, a), wherein both the action value and the prior strategy probability are output by the neural network. Like the traditional Monte Carlo tree search, the search process is divided into four stages: first is a selection stage, the selected action α combines the UCT and the judgment of the optimal action value αₜ=arg max(Q(sₜ, α)+U(sₜ, α)), wherein,

$$U ( {s}_{t} , a ) = c \cdot P ( s , a ) \frac{\sqrt{{\sum }_{b} N ( s , b )}}{1 + N ( s , b )} ,$$

which is the UCT selection strategy. The action selection is made until the final node or a leaf node. Next is an extended simulation stage. When a new leaf node which is not searched is reached, the state s of the leaf node is input into the neural network for prediction to obtain the strategy action probability P and the action value v, and the stored information of the strategy action probability P and the action value V are initialized as [N(s, α)=0, W(s, α)=0,Q(s, α)=0, P(s, α)=P]. The last is a backtracking phase, where the information on the new node is traced back to the parent node,

$$N ( s , a ) = N ( s , a ) + 1 , W ( s , a ) = W ( s , a ) + v , Q ( s , a ) = W ( s , a ) / N ( s , a ) .$$

After hundreds of searches, the agent selects a branch π(a|s)=N(s, α)^{1/τ}/ Σ_{b}N(s, b)^{1/τ} through a Monte Carlo tree strategy, wherein T is the parameter controlling the degree of exploration. In order to reduce the search space of the Monte Carlo search tree, the present disclosure adopts a rollback method for searching. In other words, when a termination state is encountered, not to mention the final wiring state, try to move forward and re-select a new action to continue.

The neural network of the agent is a ResNet (residual network) convolutional neural network (which can also be other convolutional neural networks such as VGGNet and AlexNet). The sample set obtained in the searching stage of Monte Carlo search tree of the agent is used for training the model parameters of the neural network. For each input state s, the neural network outputs p and v minimize the loss function. The first part of the loss function is the difference between the real reward and the predicted value of the neural network. The second part is a value expectation of the harvest, which is the optimization objective of the strategy gradient. The third part is a regularization term for preventing overfitting. By optimizing the deep reinforcement learning neural network, the search process of Monte Carlo search tree can be guided.

It should be noted that the reinforcement learning wiring in this embodiment adopts serial wiring, that is, sequential wiring, and certainly, parallel wiring can be used to improve the speed.

Various embodiments corresponding to the wiring method of the quantum chip are described in detail. On this basis, the present disclosure also discloses a wiring device, equipment and computer-readable storage medium of the quantum chip corresponding to the method.

The present disclosure further provides a wiring device for quantum chip. The quantum chip comprises m rows of qubit, and one row of qubit comprises n qubits, wherein both m and n are positive integers not less than 1, and for any one of the qubits, the wiring device comprising:
an initial interface determination module determining an initial interface corresponding to the qubit according to the position of the qubit on the quantum chip;
a first virtual pin interface determination module for determining a first virtual pin according to the initial interface, so that a control line in the qubit is connected with a first external pin of the quantum chip through the initial interface and the first virtual pin. A first distance between the first virtual pins corresponding to any two of the initial interfaces is not less than a preset minimum line distance; and
a first wiring module for determining a first optimal wiring path of a connecting line from the initial interface to a corresponding first virtual pin according to the initial interface, the first virtual pin and a Monte Carlo tree model, the Monte Carlo tree model is a mathematical model obtained by training on wiring results after wiring different qubits.

In some embodiments, the wiring device further comprises:
a second virtual pin interface determination module for determining a second virtual pin according to the first virtual pin, so that a control line in the qubit is connected with a second external pin of the quantum chip through the initial interface, the first virtual pin and the second virtual pin. A second distance between the second virtual pins corresponding to any two of the first virtual pins is not less than a product of the first distance and a preset expansion parameter, and the expansion parameter is greater than 1.

In some embodiments, a first horizontal ordinate formula for a horizontal ordinate of the second virtual pin is xᵢ²=xᵢ¹±d, and a first vertical ordinate formula for a vertical ordinate of the second virtual pin is

$${y}_{i}^{2} = {y}_{[ b / 2 ]}^{2} + ( [ \frac{b}{2} ] - i ) \cdot {s}^{2} ;$$

wherein, y_{[b/2]}²=y_{[b/2]}¹, xᵢ¹ is a horizontal ordinate of the i^{th} first virtual pin, xᵢ² is a horizontal ordinate of the i^{th} second virtual pin, d is a distance between the second virtual pin and the first virtual pin, yᵢ² is a vertical ordinate of the i^{th} second 1,2 virtual pin, b is the number of the first virtual pin in the row of the qubit, y_{[b/2]}² is a vertical ordinate of the b/2^{th} second virtual pin, y_{[b/2]}¹ is a vertical ordinate of the b/2^{th} first virtual pin, and s² is a second distance between each of the second virtual pins.

In some embodiments, the wiring device further comprises:
a third virtual pin interface determination module for determining a third virtual pin according to the first virtual pin, so that a control line in the qubit is connected with a third external pin of the quantum chip through the initial interface, the first virtual pin and the third virtual pin. A third distance between the third virtual pins corresponding to any two of the first virtual pins is not less than a preset minimum line distance;
the third virtual pin comprising an upper virtual pin and a lower virtual pin, the first virtual pin of the qubit row of the first row corresponding one-to-one with the upper virtual pin, the first virtual pin of the qubit row of the last row corresponding one-to-one with the lower virtual pin. The upper virtual pin is arranged above the qubit row of the first row and the lower virtual pin is arranged below the qubit row of the last row. A first distance between the upper virtual pin and the qubit row of the first row and a second distance between the lower virtual pin and the qubit row of the last row are preset optimal pin distances.

In some embodiments, the calculation formula of the optimal pin distance is as follows:

$$d = arg min ( {{\sum }^{n}}_{i} {L}_{1 i} + {L}_{2 i} ) ) ;$$

wherein, d is the optimal pin distance, n is a total number of connecting lines connecting each of the first virtual pins and the corresponding third virtual pin, L₁ᵢ is a distance from the i^{th} first virtual pin to the corresponding i^{th} third virtual pin, and L₂ᵢ is a distance from the i^{th} third virtual pin to a peripheral pin.

In some embodiments, a second horizontal ordinate formula for a horizontal ordinate of the third virtual pin is xᵢ³=x_{q1}+i·(x_{qm}−x_{q1})/(n³−1), and a second vertical ordinate formula for a vertical ordinate of the third virtual pin is

$${y}_{i}^{3} = {y}_{q 1} \pm d ;$$

wherein, xᵢ³ is a horizontal ordinate of the i^{th} third virtual pin, x_{q1} is a horizontal ordinate of an initial qubit of the qubit row of the first row or the qubit row of the last row, x_{qm} is a horizontal ordinate of a middle qubit of the qubit row of the first row or the qubit row of the last row, n³ is the number of the third virtual pin, yᵢ³ is a vertical ordinate of the i^{th} third virtual pin, y_{q1} is a vertical ordinate of an initial qubit of the qubit row of the first row or the qubit row of the last row, and d is a preset optimal pin distance.

In some embodiments, the wiring device further comprises:
a second wiring module for determining a second optimal wiring path of a connecting line from the first virtual pin to a corresponding third virtual pin according to the first virtual pin, the third virtual pin and a Monte Carlo tree model.

In some embodiments, the wiring device further comprises:
a third wiring module for connecting the third virtual pin with a corresponding third external pin according to the third virtual pin, the third external pin of the quantum chip and an A* algorithm, the third external pin corresponding one-to-one with the third virtual pin.

In some embodiments, the wiring device further comprises:
a fourth wiring module for connecting the first virtual pin with a corresponding first external pin according to the first virtual pin, the first external pin of the quantum chip and an A* algorithm, the first external pin corresponding one-to-one with the first virtual pin.

In some embodiments, the first virtual pin comprises a left half portion of the first virtual pin disposed on the left side of each of the qubit rows and a right half portion of the first virtual pin disposed on the right side of each of the qubit rows, and the calculation formula of the number of the left half portion of the first virtual pin is:

$${n}^{l 1} ( k ) = {n}_{xy}^{l} ( k ) + {n}_{z}^{l} ( k ) + {δ}^{l} ;$$

wherein, n^{l1}(k) is the number of the left half portion of the first virtual pin, n_{xy}^{l}(k) is the number of xy control lines disposed on the left side of each of the qubit rows, and n_{z}^{l}(k) is the number of z control lines disposed on the left side of each of the qubit rows;
the calculation formula of the number of the right half portion of the first virtual pin is:

$${n}^{r 1} ( k ) = {n}_{xy}^{r} ( k ) + {n}_{z}^{r} ( k ) + {δ}^{r} ;$$

wherein, n^{r1}(k) is the number of the right half portion of the first virtual pin, n_{xy}^{r}(k) is the number of xy control lines disposed on the right side of each of the qubit rows, n_{z}^{r}(k) is the number of z control lines disposed on the right side of each of the qubit rows, δ^{l} is 0 or 1, δ^{r} is 0 or 1, and δ^{l}+δ^{r}=1.

In some embodiments, the wiring device further comprises:
a reward function module for scoring wiring results of the first optimal wiring path according to a reward function; and
a Monte Carlo tree update module for updating the Monte Carlo tree model according to the scoring result and a neural network model.

In some embodiments, the reward function is defined as:

$$R ( s , a ) = \{ \begin{matrix}- α \sum {L}_{i} - β \sum {L}_{ri} - γ \sum {N}_{i} , {s}^{′} ∈ t \\ 0 , t ⋂ {s}^{′} = ⌀\end{matrix} ;$$

wherein, s is a wiring state in the wiring process of the first optimal wiring path, α is a wiring action in the wiring process of the first optimal wiring path, Lᵢ is a wiring length of the first optimal wiring path, Lᵣᵢ is a Manhattan length between the i^{th} unwired initial interfaces, Nᵢ is the number of right angles in the wiring process of the first optimal wiring path, α, β and γ are weight coefficients in front of each item, s′ is a wiring state after the wiring action α is performed, and t is a state of completing the wiring of all the initial interfaces or a state where the wiring cannot be continued.

In some embodiments, a loss function of the neural network model is:

$$L = {( R - v )}^{2} + {E}_{p} [ log ( {p}_{θ} ( s , a ) \cdot v ( s , a ) ] + α {\vert θ \vert}^{2} ;$$

wherein, L is the loss function, s is a wiring state in the wiring process of the first optimal wiring path, α is a wiring action in the wiring process of the first optimal wiring path, R is the reward function, v is a value function output by the neural network model when a wiring states and a wiring action α are input to the neural network model, p_{θ} is a policy function output by the neural network model when a wiring state s and a wiring action α are input to the neural network model, α is a regularization parameter of the neural network model, and θ is a parameter of the neural network model.

For the description of the wiring device for the quantum chip provided by the present disclosure, please refer to the above embodiments, and the present disclosure will not be described in detail herein.

The present disclosure further provides a wiring equipment for quantum chip. The quantum chip comprises m rows of qubit, and one row of qubit comprises n qubits, wherein both m and n are positive integers not less than 1, and for any one of the qubits, the wiring equipment comprising:
a memory for storing a computer program; and
a processor for implementing the steps of a wiring method for quantum chip as described in any one of the above embodiments when executing the computer program.

For the description of the wiring equipment for the quantum chip provided by the present disclosure, please refer to the above embodiments, and the present disclosure will not be described in detail herein.

The present disclosure further provides a computer-readable storage medium, wherein the target computer-readable storage medium has a computer program stored thereon. The target computer program is executed by a processor to implement the steps of a wiring method for quantum chip as described in any one of the above embodiments.

For the description of the computer-readable storage medium provided by the present disclosure, please refer to the above embodiments, and the present disclosure will not be described in detail herein.

It should also be noted that relationship terms such as first and second, etc. are used herein only to distinguish one entity or operation from another without necessarily requiring or implying any such actual relationship or order between those entities or operations. Moreover, the terms “comprise”, “include” or any other variation thereof, are intended to cover a non-exclusive inclusion, such that a process, a method, an article, or an apparatus comprising a list of elements includes not only those elements, but also other elements not explicitly listed or may include elements inherent to the process, method, article, or apparatus. Without further limitation, an element defined by the statement of “comprising a . . . ” does not exclude the further presence of additionally identical elements in a process, a method, an article or an apparatus comprising said element.

Those skilled in the art may further realize that the units and algorithmic steps of the examples described in conjunction with the embodiments disclosed herein can be implemented in electronic hardware, computer software, or a combination thereof. To clearly illustrate the interchangeability of hardware and software, the components and steps of the examples have been described generally in terms of function in the above description. Whether these functions are performed in hardware or software depends on the particular application and design constraints of the technical solution. Those skilled in the art may use different methods to implement the described functions for each particular application, but such implementations should not be considered as going beyond the scope of the present disclosure.

The steps of the methods or algorithms described in conjunction with the embodiments disclosed herein may be implemented directly with hardware, a software module executed by a processor, or a combination thereof. A software module may be placed in random access memory (RAM), memory, read-only memory (ROM), electrically programmable ROM, electrically erasable programmable ROM, a register, a hard disk, a removable diskette, a CD-ROM, or any other form of storage medium known in the art.

What is claimed is:

1. A wiring method for quantum chip, wherein the quantum chip comprises m rows of qubits, and one row of qubits comprises n qubits, wherein both m and n are positive integers not less than 1, and for any one of the qubits, the wiring method comprises:
determining an initial interface corresponding to the qubit according to a position of the qubit on the quantum chip;
determining a first virtual pin according to the initial interface, so that a control line in the qubit is connected with a first external pin of the quantum chip through the initial interface and the first virtual pin, and a first distance between the first virtual pins corresponding to any two of the initial interfaces is not less than a preset minimum line distance; and
determining a first optimal wiring path of a connecting line from the initial interface to a corresponding first virtual pin according to the initial interface, the first virtual pin and a Monte Carlo tree model, the Monte Carlo tree model is a mathematical model obtained by training on wiring results after wiring different qubits.

2. The wiring method for quantum chip of claim 1, after determining a first virtual pin according to the initial interface, further comprising:
determining a second virtual pin according to the first virtual pin, so that a control line in the qubit is connected with a second external pin of the quantum chip through the initial interface, the first virtual pin and the second virtual pin, and a second distance between the second virtual pins corresponding to any two of the first virtual pins is not less than a product of the first distance and a preset expansion parameter, and the expansion parameter is greater than 1.

3. The wiring method for quantum chip of claim 2, wherein a first horizontal ordinate formula for a horizontal ordinate of the second virtual pin is xᵢ²=xᵢ¹±d, and a first vertical ordinate formula for a vertical ordinate of the second virtual pin is
$${y}_{i}^{2} = {y}_{[ b / 2 ]}^{2} + ( [ \frac{b}{2} ] - i ) \cdot {s}^{2} ;$$
wherein, y_{[b/2]}²=y_{[b/2]}¹, xᵢ¹ is a horizontal ordinate of the i^{th} first virtual pin, xᵢ² is a horizontal ordinate of the i^{th} second virtual pin, d is a distance between the second virtual pin and the first virtual pin, yᵢ² is a vertical ordinate of the i^{th} second virtual pin, b is the number of the first virtual pin in the row of the qubit, y_{[b/2]}² is a vertical ordinate of the b/2^{th} second virtual pin, y_{[b/2]}¹ is a vertical ordinate of the b/2^{th} first virtual pin, and s² is a second distance between each of the second virtual pins.

4. The wiring method for quantum chip of claim 1, after determining a first virtual pin according to the initial interface, further comprising:
determining a third virtual pin according to the first virtual pin, so that a control line in the qubit is connected with a third external pin of the quantum chip through the initial interface, the first virtual pin and the third virtual pin, and a third distance between the third virtual pins corresponding to any two of the first virtual pins is not less than a preset minimum line distance; and
the third virtual pin comprising an upper virtual pin and a lower virtual pin, the first virtual pin of the qubit row of the first row corresponding one-to-one with the upper virtual pin, the first virtual pin of the qubit row of the last row corresponding one-to-one with the lower virtual pin, the upper virtual pin is arranged above the qubit row of the first row and the lower virtual pin is arranged below the qubit row of the last row, and a first distance between the upper virtual pin and the qubit row of the first row and a second distance between the lower virtual pin and the qubit row of the last row are preset optimal pin distances.

5. The wiring method for quantum chip of claim 4, wherein the calculation formula of the optimal pin distance is as follows:
$$d = arg min ( {{\sum }^{n}}_{i} {L}_{1 i} + {L}_{2 i} ) ) ;$$
wherein, d is the optimal pin distance, n is a total number of connecting lines connecting each of the first virtual pins and the corresponding third virtual pin, L₁ᵢ is a distance from the i^{th} first virtual pin to the corresponding i^{th} third virtual pin, and L₂ᵢ is a distance from the i^{th} third virtual pin to a peripheral pin.

6. The wiring method for quantum chip of claim 4, wherein a second horizontal ordinate formula for a horizontal ordinate of the third virtual pin is xᵢ³=x_{q1}+i·(x_{qm}−x_{q1})/(n³−1), and a second vertical ordinate formula for a vertical ordinate of the third virtual pin is yᵢ³=y_{q1}±d;
wherein, xᵢ³ is a horizontal ordinate of the i^{th} third virtual pin, x_{q1} is a horizontal ordinate of an initial qubit of the qubit row of the first row or the qubit row of the last row, x_{qm} is a horizontal ordinate of a middle qubit of the qubit row of the first row or the qubit row of the last row, n³ is the number of the third virtual pin, yᵢ³ is a vertical ordinate of the i^{th} third virtual pin, y_{q1} is a vertical ordinate of an initial qubit of the qubit row of the first row or the qubit row of the last row, and d is a preset optimal pin distance.

7. The wiring method for quantum chip of claim 4, after determining a third virtual pin according to the first virtual pin, further comprising:
determining a second optimal wiring path of a connecting line from the first virtual pin to a corresponding third virtual pin according to the first virtual pin, the third virtual pin and a Monte Carlo tree model.

8. The wiring method for quantum chip of claim 7, after determining a second optimal wiring path of a connecting line from the first virtual pin to a corresponding third virtual pin according to the first virtual pin, the third virtual pin and a Monte Carlo tree model, further comprising:
connecting the third virtual pin with a corresponding third external pin according to the third virtual pin, the third external pin of the quantum chip and an A* algorithm, the third external pin corresponding one-to-one with the third virtual pin.

9. The wiring method for quantum chip of claim 7, after determining a first optimal wiring path of a connecting line from the initial interface to a corresponding first virtual pin according to the initial interface, the first virtual pin and a Monte Carlo tree model, further comprising:
connecting the first virtual pin with a corresponding first external pin according to the first virtual pin, the first external pin of the quantum chip and an A* algorithm, the first external pin corresponding one-to-one with the first virtual pin.

10. The wiring method for quantum chip of claim 1, wherein the first virtual pin comprises a left half portion of the first virtual pin disposed on the left side of each of the qubit rows and a right half portion of the first virtual pin disposed on the right side of each of the qubit rows, and the calculation formula of the number of the left half portion of the first virtual pin is:
$${n}^{l 1} ( k ) = {n}_{xy}^{l} ( k ) + {n}_{z}^{l} ( k ) + {δ}^{l} ;$$
wherein, n^{l1}(k) is the number of the left half portion of the first virtual pin, n_{xy}^{l}(k) is the number of xy control lines disposed on the left side of each of the qubit rows, and n_{z}^{l}(k) is the number of z control lines disposed on the left side of each of the qubit rows;
the calculation formula of the number of the right half portion of the first virtual pin is:
$${n}^{r 1} ( k ) = {n}_{xy}^{r} ( k ) + {n}_{z}^{r} ( k ) + {δ}^{r} ;$$
wherein, n^{r1}(k) is the number of the right half portion of the first virtual pin, n_{xy}^{r}(k) is the number of xy control lines disposed on the right side of each of the qubit rows, n_{z}^{r}(k) is the number of z control lines disposed on the right side of each of the qubit rows, δ^{l} is 0 or 1, δ^{r} is 0 or 1, and δ^{l}+δ^{r}=1.

11. The wiring method for quantum chip of claim 1, after determining a first optimal wiring path of a connecting line from the initial interface to a corresponding first virtual pin according to the initial interface, the first virtual pin and a Monte Carlo tree model, further comprising:
scoring wiring results of the first optimal wiring path according to a reward function; and
updating the Monte Carlo tree model according to the scoring result and a neural network model.

12. The wiring method for quantum chip of claim 11, wherein the reward function is defined as:
$$R ( s , a ) = \{ \begin{matrix}- α \sum {L}_{i} - β \sum {L}_{ri} - γ \sum {N}_{i} , {s}^{′} ∈ t \\ 0 , t ⋂ {s}^{′} = ⌀\end{matrix} ;$$
wherein, s is a wiring state in the wiring process of the first optimal wiring path, α is a wiring action in the wiring process of the first optimal wiring path, Lᵢ is a wiring length of the first optimal wiring path, Lᵣᵢ is a Manhattan length between the i^{th} unwired initial interfaces, Nᵢ is the number of right angles in the wiring process of the first optimal wiring path, α, β and γ are weight coefficients in front of each item, s′ is a wiring state after the wiring action a is performed, and t is a state of completing the wiring of all the initial interfaces or a state where the wiring cannot be continued.

13. The wiring method for quantum chip of claim 11, wherein a loss function of the neural network model is:
$$L = {( R - v )}^{2} + {E}_{p} [ log ( {p}_{θ} ( s , a ) \cdot v ( s , a ) ] + α {\vert θ \vert}^{2} ;$$
wherein, L is the loss function, s is a wiring state in the wiring process of the first optimal wiring path, α is a wiring action in the wiring process of the first optimal wiring path, R is the reward function, v is a value function output by the neural network model when a wiring state s and a wiring action α are input to the neural network model, p_{θ} is a policy function output by the neural network model when a wiring state s and a wiring action α are input to the neural network model, α is a regularization parameter of the neural network model, and θ is a parameter of the neural network model.

14. A wiring device for quantum chip, wherein the quantum chip comprises m rows of qubit, and one row of qubit comprises n qubits, wherein both m and n are positive integers not less than 1, and for any one of the qubits, the wiring device comprising:
an initial interface determination module determining an initial interface corresponding to the qubit according to the position of the qubit on the quantum chip;
a first virtual pin interface determination module for determining a first virtual pin according to the initial interface, so that a control line in the qubit is connected with a first external pin of the quantum chip through the initial interface and the first virtual pin, and a first distance between the first virtual pins corresponding to any two of the initial interfaces is not less than a preset minimum line distance; and
a first wiring module for determining a first optimal wiring path of a connecting line from the initial interface to a corresponding first virtual pin according to the initial interface, the first virtual pin and a Monte Carlo tree model, the Monte Carlo tree model is a mathematical model obtained by training on wiring results after wiring different qubits.

15. A wiring equipment for quantum chip, wherein the quantum chip comprises m rows of qubit, and one row of qubit comprises n qubits, wherein both m and n are positive integers not less than 1, and the wiring equipment comprising:
a memory for storing a computer program; and
a processor for implementing the steps of a wiring method for quantum chip as claimed in claim 1 when executing the computer program.
